(19) United States
(12) Patent Application Publication
(10) Pub. No.: US 2025/0206184 A1
(43) Pub. Date: Jun. 26, 2025

(54) METHOD AND SYSTEM TO CONTROL AND MONITOR A VEHICLE BATTERY PACK USING A BATTERY IMPEDANCE MODEL

(71) Applicant: Ford Global Technologies, LLC, Dearborn, MI (US)

(72) Inventors: David Bilby, Royal Oak, MI (US); Nathan Kempema, Grosse Pointe Farms, MI (US); Richard Dyche Anderson, Plymouth, MI (US)

(21) Appl. No.: 18/392,631

(22) Filed: Dec. 21, 2023

(51) Int. Cl. B60L 58/12; G01R 31/367; H01M 10/48

(52) U.S. Cl. CPC B60L 58/12; G01R 31/367; H01M 10/488

(57) ABSTRACT

An electrified vehicle (EV) includes a battery pack, one or more sensors, and a vehicle controller. The battery pack includes a plurality of battery cells and is operable to provide at least a portion of propulsion power. The vehicle controller is configured to charge and discharge the battery pack according to power limits defined by output of a battery impedance model. The battery impedance model associates battery impedance values with frequency-dependent polarization impedance values representing diffusion states of the battery cells, and receives measured parameters from the one or more sensors indicative of the frequency-dependent polarization impedance values of the battery pack.

### TECHNICAL FIELD

The present disclosure generally relates to managing and/or controlling a battery pack for an electrified vehicle.

### BACKGROUND

An electrified vehicle (EV) includes a battery pack, sometimes referred to as a traction battery, for providing power to electric motors to propel the EV. One or more operational characteristics of the battery pack, such as temperature, power limit, and/or state of charge (SOC), may be measured/estimated to control the charge and discharge operation of the battery pack.

In a non-limiting example, the EV includes a battery management module (BMM) and a control system. Generally, during a discharge operation (e.g., driving of the EV), the BMM is configured to estimate SOC and/or power limits of the battery pack, and the control system is configured to control various devices/subsystems within the EV by, for example, determining how much power can be drawn from the battery pack using the operational characteristics, inputs from a user, power demand of devices (e.g., motors, air condition system, etc.), and/or among other information. For a charge operation, the BMM is configured to provide a charge current/voltage request to the control system, which in return controls the EV to begin charging the battery pack (e.g., control an electric vehicle supply equipment (EVSE)).

### SUMMARY

In one form, the present disclosure is directed towards an electrified vehicle (EV), that includes a battery pack, one or more sensors, and a vehicle controller. The battery pack includes a plurality of battery cells and is operable to provide at least a portion of propulsion power. The vehicle controller is configured to charge and discharge the battery pack according to power limits defined by output of a battery impedance model. The battery impedance model associates battery impedance values with frequency-dependent polarization impedance values representing diffusion states of the battery cells, and receives measured parameters from the one or more sensors indicative of the frequency-dependent polarization impedance values of the battery pack.

In another form, the present disclosure is directed to a method of operating an electrified vehicle (EV) having a battery pack including a plurality of battery cells. The method includes charging and discharging the battery pack according to power limits defined by output of a battery impedance model. The battery impedance model associates battery impedance values with frequency-dependent polarization impedance values representing diffusion states of the battery cells, and receives measured parameters from the one or more sensors indicative of the frequency-dependent polarization impedance values of the battery pack.

In one form, the present disclosure is directed toward a system for an electrified vehicle (EV) that includes a vehicle controller configured to charge and discharge the battery pack according to power limits defined by output of a battery impedance model. The battery impedance model associates battery impedance values with frequency-dependent polarization impedance values representing diffusion states of the battery cells, and receives measured parameters from one or more sensors indicative of the frequency-dependent polarization impedance values of the battery pack.

### BRIEF DESCRIPTION OF THE DRAWINGS

FIG. 1 is an example block diagram of an electrified vehicle (EV) in accordance with the present disclosure;

FIG. 2 is a block diagram of a battery pack of the EV in accordance with the present disclosure;

FIG. 3 is a block diagram of a BMM of the EV in accordance with the present disclosure; and

FIG. 4 is a flowchart of battery control routine in accordance with the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

Generally, battery characteristics, such as but not limited, power capability and energy capacity, are controlled and monitored based on voltage, current, and temperature measurements interpreted by carefully designed and calibrated models. These models and calibrations can require time intensive development and may not capture all relevant operations, such as aging.

In some instances, electrochemical impedance spectroscopy (EIS) may be used to capture additional information about chemical processes within the battery cell that influence the battery characteristics. EIS involves phase-sensitive measurement of voltage and current in response to electrical perturbation as a function of frequency. Different battery processes, like liquid and solid diffusion, and lithium intercalation charge transfer reactions, have distinct impedance response at different frequencies. Moreso, EIS can potentially be implemented for on-board monitoring by increasing the sampling rate of existing battery voltage and current measurements. Unfortunately, traditional EIS measurements are performed using, for example, single-frequency sinusoidal excitation or broadband excitation methods, leading to long acquisition times for low frequency measurements (f<0.1 Hz).

The present disclosure is directed to a system that controls operation of the battery pack using an output of a battery impedance model defined to estimate the low frequency impedance behavior of the battery pack to obtain a complete characterization of battery impedance. Specifically, the battery impedance model is defined to associate battery impedance values with frequency-dependent polarization impedance values representing diffusion states of battery cells of the battery pack.

More particularly, low frequency impedance of battery cells is typically dominated by diffusion, and by accurately knowing/modeling diffusion, the battery pack may be controlled more accurately. For example, direct current (DC) power delivery is dominated by diffusion, which is a limiting factor at low temperatures. In addition, internal battery polarization occurs when external potential application exceeds the diffusion-limited battery capability. For example, if too much current is pushed during fast charging, internal polarization can lead to potentials that cause lithium plating. Lithium plating increases battery degradation (capacity loss) and can lead to thermal runaway if lithium dendrites grow to short-circuit.

Extraction of parameters that describe physical battery processes may require deconvolving overlapping EIS features. Generally, this means sampling a broad range of frequencies, especially those that are dominated by individual processes. Low frequency is typically dominated by diffusion, but under some conditions there is charge transfer overlapping with the diffusion at moderately low frequencies. In that case, even lower frequencies are sampled to characterize the diffusion and charge feature contributions separately.

The battery impedance model of the present disclosure characterizes electrochemical battery processes to more accurately control power and energy of the battery pack, and to track the aging of the battery pack. As detailed herein, a battery management module of the EV is configured to employ the battery impedance model to define a low frequency battery impedance value that is used to control the battery pack 106 and thus, the EV.

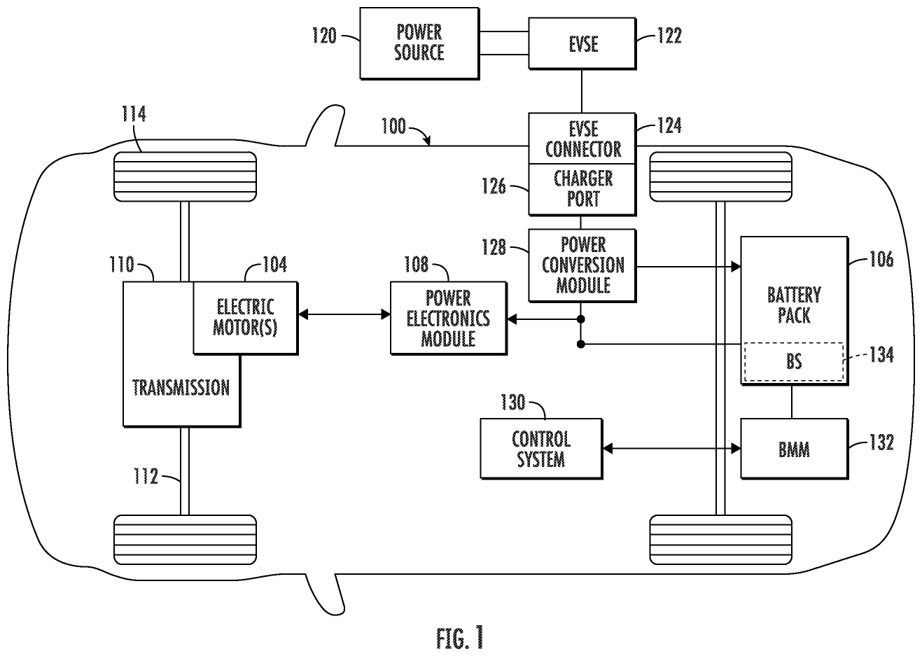

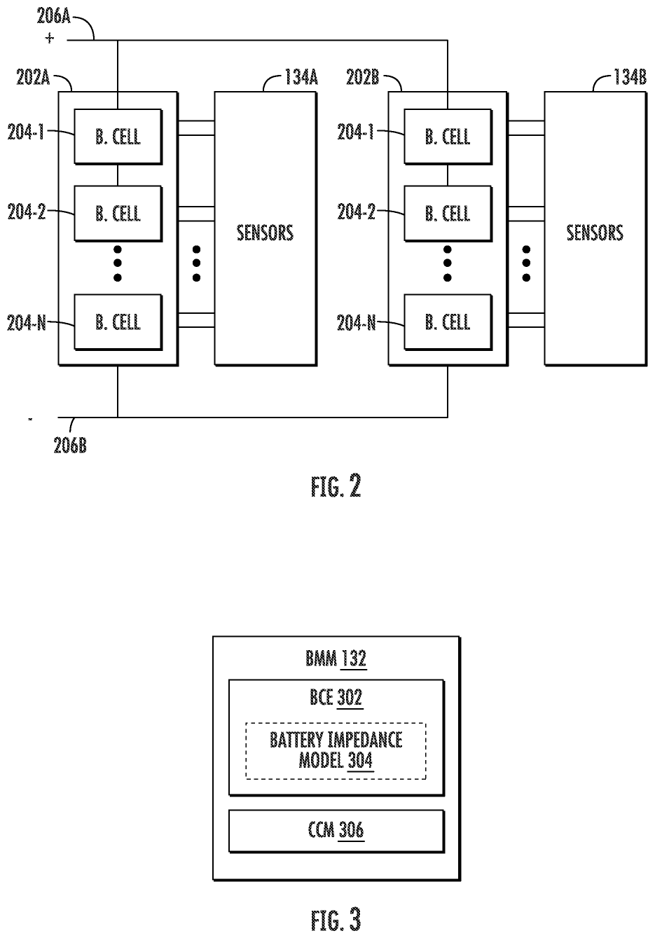

Referring to FIGS. 1 and 2, in one form, an EV 100 is provided as a fully battery electric vehicle (BEV) powered by electric motors. In a non-limiting example, the EV 100 includes a powertrain system having one or more electric motors 104 (i.e., electric machines), a battery pack 106 (i.e., a traction battery), and a power electronics module 108. The EV 100 of the present disclosure does not include an engine, and thus, the battery pack 106 provides all of the propulsion power. In other variations, the present disclosure may be applied to other types of EVs having a high voltage battery pack, such as, but not limited to, a hybrid electric vehicle (plug-in or non-plug-in) having an engine and fuel cell electric vehicles. In addition, the EV is not limited to four-wheel automobiles and may apply to scooters, three-wheel vehicles, aerial vehicles, and/or among other electrified vehicles.

The electric motor 104 provides power movement of the EV 100, and in a non-limiting example, is mechanically connected to a transmission 110 that is mechanically connected to a drive shaft 112, which is mechanically connected to wheels 114 of the EV 100. In addition to providing propulsion power, the electric motor 104 may be configured to operate as a generator to recover energy that may normally be lost as heat in a friction braking system of EV 100.

The battery pack 106 provides a high-voltage (HV) direct current (DC) output that is employed to power the electric motor 104 via the power electronics module 108. In one form, the power electronics module 108, which includes an inverter, provides a bi-directional transfer energy between the battery pack 106 and the electric motor 104. Specifically, as known, the power electronics module 108 converts the DC voltage to a three-phase AC current to operate the electric motor 104, and in a regenerative mode, the power electronics module 108 converts three-phase AC current from the electric motor 104, which is acting as a generator, to DC voltage compatible with the battery pack 106.

The battery pack 106 may be rechargeable by an external power source 120 (e.g., the grid), which is electrically connected to an electric vehicle supply equipment (EVSE) 122. The EVSE 122 provides circuitry and controls to manage the transfer of electrical energy between the external power source 120 and the EV 100. The external power source 120 may provide DC or AC electric power to the EVSE 122. The EVSE 122 may have a charge connector 124 for plugging into a charge port 126 of the EV 100.

The EV 100 may further include a power conversion module 128 that is an on-board charger having a DC/DC converter to condition power supplied from the EVSE 222 and provide the proper voltage and current levels to the battery pack 106. The power conversion module 228 may interface with the EVSE 222 to coordinate the delivery of power to the battery pack 106.

In addition to providing electrical energy for propulsion, the battery pack 106 may provide electrical energy for use by other electrical systems in the EV 100, such as HV loads like electric heater and air-conditioner systems, and low-voltage (LV) loads like an auxiliary battery. In some variations, the battery pack 106 is configured to have bidirectional power transfer capability to provide power to systems outside of the EV 100 (i.e., external system) such as, but not limited to, home, business, and/or a microgrid. In a non-limiting example, the battery pack 106 is electrically coupled to the external system using the EVSE connector 224 and is operable to provide energy based on a transient load recommended for the external system and an amount of energy available from the battery pack 106.

In one form, the EV 100 includes a control system 130 to coordinate the operation of the various components. The control system 130 includes electronics, software, or both, to perform the necessary control functions for operating the EV 100. The control system 130 may be a combination vehicle control system and powertrain control module (VSC/PCM). Although the control system 130 is shown as a single device, the control system 130 may include multiple controllers in the form of multiple hardware devices, or multiple software controllers with one or more hardware devices. In this regard, a reference to a “controller” herein may refer to one or more controllers.

In one form, the EV 100 includes a battery management module (BMM) 132 configured to estimate one or more operating characteristics of the battery pack 106. The BMM 132 is in communication with one or more sensors 134 provided with the battery pack 106 to detect characteristics of the battery pack 106, such as but not limited to, electric current, voltage, and/or temperature. The BMM 132 may form part of the vehicle control system with the control system 130 and while illustrated separate from the control system 130, may be integrated with the control system 130. Using the operating characteristics of the battery pack 106, the control system 130 is configured to draw power from the battery pack 106 based on driver demand and other considerations. In one form, the BMM 132 and the control system 130 may be referred to as a vehicle controller.

The BMM 132 is further configured to operate contactors (not shown) to electrically couple/decouple the battery pack 106 to/from a charge-discharge system of the EV based on a command from the control system 130. The charge-discharge system of the EV includes components that either charge the battery pack 106 or act as a load to draw electric power from the battery pack 106, and thus, may include the charge port 126, the power electronics module 108, and/or the transmission 110, among other components.

Among other components, the battery pack 106 includes multiple battery arrays 202A and 202B (collectively “arrays 202”), where each array 202 includes a plurality of battery cells 204-1 to 204-N (collectively “cells 204”) connected in series (FIG. 2). The arrays 202 are connected to a positive power bus 206A and a negative power bus 206B (collectively “power buses 206”). While two arrays 202 are provided, the battery pack 106 may include one or more arrays 202, and should not be limited to the example provided herein. In addition, while the arrays 202 are illustrated as being in parallel, the arrays 202 may be configured to be operable in parallel and/or in series with the use of power switches.

The sensors 134 includes one or more sensors 134A and 134B for the arrays 202. In one form, the sensors 134 measure various parameters (i.e., measured parameters) related to the operation/performance of the battery pack 106. In a non-limiting example, the measured parameters may include: electrical characteristics (e.g., voltage and/or current) of the arrays 202 and/or the battery cells 204, and/or temperature of the battery pack 106. Accordingly, the sensors 134 may include voltage sensors, current sensors, and temperature sensors, among other sensing devices.

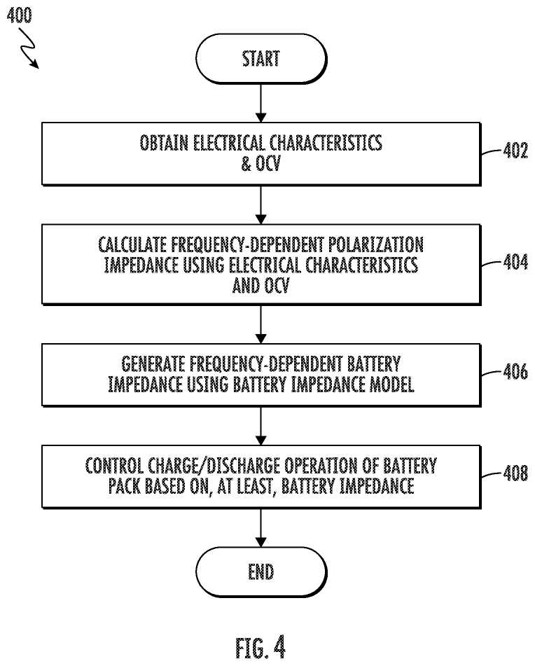

Referring to FIG. 3, in one form, the BMM 132 includes a battery characteristic estimator (BCE) 302 having the battery impedance model 304 and a contactor control module (CCM) 306 configured to operate the contactors in the closed/open positions based on a command from the control system 130.

The BCE 302 is configured to estimates various operational characteristics of the battery pack 106, such as but not limited to, electrical characteristic of the battery pack 106 (e.g., electrical characteristic of each battery cell 204, of each array 202, and of the battery pack 106 as a whole), the OCV of each battery cell, the SOC of the battery pack 106, the power limit of the battery pack 106, and temperature of the battery pack 106.

In one form, the battery impedance model 304 associates battery impedance values with frequency-dependent polarization impedance values representing diffusion states of the battery cells, and receives measured parameters indicative of the frequency-dependent polarization impedance values of the battery pack 106 from the sensors 134. Specifically, the frequency-dependent polarization impedance values are generally low frequency polarization impedance of the battery cells 204 which is typically dominated by diffusion. The battery impedance at low frequency can be obtained by: (1) measuring electrical characteristic of the battery pack 106, (2) obtaining the OCV, (3) calculating polarization voltage, (4) calculating polarization resistance, and (5) estimate complex impedance at low frequency using the battery impedance model 304 and the polarization resistance. The battery impedance may be provided for the battery pack 106 as whole, multiple arrays of battery cells 204 within the battery pack 106, and/or on individually measured battery cells 204, depending on, for example, need of the control system 130 and diagnostics.

The electrical characteristics of the battery pack 106 includes a DC voltage and an electric current of the battery pack 106, which are measured by the sensors 134. In a non-limiting example, electric current is measured over the entire battery pack 106 and voltage is measured across each set of parallel battery cells 204. In addition, the current and voltage of the battery pack 106 may be sampled at 500 Hz, and the voltage of the cells 204 may be sampled at 10 Hz. The sampling rate of the electric current may be selected to meet Nyquist sampling criteria to integrate the electric current within selected accuracy criteria. In one form, the DC voltage is measurably different from the OCV, and the electric current should be large enough to create polarization but may depend on battery chemistry, temperature, and/or age of the battery pack 106/cell 204. Accordingly, the electrical characteristics measured when the EV 100 is charging/discharging may be used for the low frequency battery impedance estimate. In some applications, there may also be a need for a certain amount of time and/or stability (rate of change) at the current and voltage difference measurements to ensure accuracy of the low frequency battery impedance estimate.

The polarization impedance is a function of the OCV, which is the voltage of the battery pack 106 at rest. When the EV 100 is not operating (i.e., no charging and no discharging), the OCV may be determined using known techniques, which may include measuring voltage of each battery cells and using known models/algorithms to estimate the OCV. When the EV 100 is charging or discharging, the OCV is estimated based on a battery state of charge (SOC) and a defined correlation between multiple battery SOC values and OCV values, and may be referred to as SOC-OCV correlation. The SOC-OCV correlation is typically found through a careful calibration process with long wait times across the range of SOC. For example, four hours of equilibration time may be necessary in large cells, but the value varies with cell construction, chemistry, SOC, temperature, and electrical current history. The SOC-OCV correlation is assumed to be accurate and appropriate for the battery state (i.e., power limit, SOC, temperature, capacity when battery pack 106 is fully charged, and/or other variable describing health/capability of the battery pack 106) and the conditions that the battery pack 106 is operating under. The accuracy of the SOC-OCV may be dependent on the type of EV, and may include, but is not limited to, 1% accuracy for a BEV and 5% accuracy for HEV. The SOC may be determined using known techniques such as, but not limited to, a SOC algorithm/model, and completion of a standard charge, which corresponds to SOC. In one form, in addition to SOC, the OCV is estimated using a temperature of the battery pack 106 or battery cells 204, and therefore the SOC-OCV correlation is defined to associated OCV with SOC and temperature.

The polarization voltage is determined using equation 1 below in which “V_{P}” is the polarization voltage, “V_{DC}” is the DC voltage, and “V_{OC}” is the open circuit voltage. The polarization voltage is the absolute value of the difference between the OCV and the measured DC voltage of the battery pack 106.

$${V}_{P} = \sqrt{{( {V}_{D C} - {V}_{O C} )}^{2}} \qquad Equation 1$$

Using the polarization voltage, the polarization resistance (R_{P}) is calculated using equation 2, where I_{DC} is the electric current. Alternately, an empirically calibrated non-linear equation, like the Butler-Volmer equation, can be used, to relate voltage, current and zero-current impedance.

$${R}_{P} = \frac{{V}_{P}}{{I}_{D C}} \qquad Equation 2$$

The complex impedance at low frequency is obtained using the battery impedance model 304 and the polarization resistance, which is the real component of complex frequency-dependent impedance (Z) at low frequency. The battery impedance model 304 is defined to extrapolate from real polarization impedance to imaginary polarization impedance, and fits impedance data with different relative behavior between the real and imaginary components at the low frequency limit. In a non-limiting example, the battery impedance model is defined using at least one of semi-infinite Warburg model, a reflective-boundary Warburg model, a transmissive-boundary Warburg model, or a constant phase element based model. These models assume low frequency behavior dominates and ignores mid and high frequency behavior. For example, semi-infinite Warburg impedance characterizes low frequency impedance using equations 3 and 4, in which “Z_{W}” is Warburg impedance, “ω” is angular frequency, “R” is gas constant, “T” is temperature of the electrochemical system, “a” is surface area, “n” is valence, “F” is faraday constant, “Cₒₓ” is concentration of oxidized species, “Dₒₓ” is diffusion coefficient of oxidized species, “C_{red}” is concentration of reduced species, and “D_{red}” is diffusion coefficient of reduced species. The Warburg model provides a relationship between real and imaginary components of complex impedance. Specifically, in equation 3, “A/\sqrt{ω}” is real component and “A/i\sqrt{ω}” is imaginary component. Accordingly, equation 3 may be provided as equation 5, where R_{P} is the polarization resistance.

$${Z}_{W} ( ω ) = \frac{A}{\sqrt{ω}} + \frac{A}{i \sqrt{ω}} \qquad Equation 3$$

$$A = \frac{R T}{\sqrt{2} \cdot a \cdot {( n F )}^{2}} ( \frac{1}{{C}_{o x} \sqrt{{D}_{o x}}} + \frac{1}{{C}_{r e d} \sqrt{{D}_{r e d}}} ) \qquad Equation 4$$

$${Z}_{W} ( ω ) = {R}_{P} + \frac{A}{i \sqrt{ω}} \qquad Equation 5$$

The battery impedance model 304 may be calibrated during development or in-situ. For in-situ calibration, the low frequency impedance can be directly measured using the traditional single-sine excitation or broadband excitation, and the measured data is then fit to the desired model to extract the relationship between real and imaginary impedance. This fit relationship may then be assumed as constant (or saved in on-board memory of the EV 100) as the battery impedance model 304 as a function of another state variable like SOC or temperature of battery cell/battery pack. The lookup table is defined to enforce a relationship between the real and imaginary impedance, thereby allowing lookup of the imaginary impedance magnitude for a given estimate of real impedance magnitude that is the measured polarization resistance.

The output of the battery impedance model 304 is then used to control the charging and/or discharging of the battery pack 106. For example, using known techniques, the battery impedance is used to determine a power limit of the battery pack 106, which is used to inhibit over discharge of the battery pack 106 and to control life of the battery pack 106. In a non-limiting example, a Fourier transform of measured battery impedance from frequency to time dependent variable space may be used to estimate a power capability of the battery pack 106. The time dependent impedance, in combination with a model relating battery current, voltage and impedance, like Ohm's law or the Butler-Volmer equation, enables calculation of available electrical power. Battery impedance may also be used to monitor factors related to lithium plating or thermal runaway.

In some variations, the battery impedance may also be used to estimate the state of health (SOH) of the battery pack or estimate an available energy of the battery pack 106. The SOH is a diagnostic for monitoring the life of the battery pack 106. The available energy may be an input to a distance-to-empty calculations in the EV 100.

The output of the battery impedance model 304 may be used for other managing/controlling aspects of the battery pack 106, and should not be limited to the examples herein.

Referring to FIG. 4, an example battery control routine 400 performed by the BMM 132 and the control system 130 is provided. At 402, the BMM 132 obtains electrical characteristics (e.g., measured parameters) and the OCV of the battery pack 106, as described above. At 404, the BMM 132 calculates or estimates the real impedance value (i.e., a frequency-dependent polarization impedance) using the electrical characteristics and the OCV. As provided above, the real impedance at low frequency is the polarization resistance, which is determined using electrical characteristics from the sensors 134 and the OCV. At 406, the BMM 132 generates a frequency-dependent battery impedance based on the battery impedance model 304. Specifically, using the frequency-dependent polarization impedance, the battery impedance model 304 provides a low frequency battery impedance (i.e., a frequency dependent battery impedance representing diffusion states of the battery cells). The control system 130 is configured to control the charge/discharge operation of the battery pack 106 based on the battery impedance, at 408. For example, the BMM 132 determines a power limit of the battery pack 106 using the battery impedance, which is used to control the charge/discharge operation of the EV by the control system 130. It should be readily understood that the routine 400 is just one example of the control operation of the BMM 132 having the battery impedance model 304 and other routines may be used within the scope of the disclosure.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

In this application, the term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term memory or memory device is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented as one or more special purpose compute(s) r created by configuring a general-purpose computer to execute one or more particular functions embodied in computer programs. In addition, computing devices, like the special purpose computer(s), may be in communication with each other and other devices in the vehicle (e.g., sensors) using a communication network (e.g., CAN and/or Ethernet, among other networks). The functional blocks, flowchart components, and other elements described above serve as software specifications, which can be translated into the computer programs by the routine work of a skilled technician or programmer.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. An electrified vehicle (EV), comprising:
a battery pack including a plurality of battery cells and operable to provide at least a portion of propulsion power;
one or more sensors; and
a vehicle controller configured to charge and discharge the battery pack according to power limits defined by output of a battery impedance model that associates battery impedance values with frequency-dependent polarization impedance values representing diffusion states of the battery cells, and that receives measured parameters from the one or more sensors indicative of the frequency-dependent polarization impedance values of the battery pack.

2. The electrified vehicle of claim 1, wherein the frequency-dependent polarization impedance values are a function of, at least, an open circuit voltage (OCV) detected based on a battery state of charge (SOC) and a defined correlation between multiple battery SOC values and OCV values.

3. The electrified vehicle of claim 1, wherein the measured parameters include a DC voltage and an electric current of the battery pack.

4. The electrified vehicle of claim 3, wherein the frequency-dependent polarization impedance values are a function of the electric current and a polarization voltage estimated using the DC voltage and an open circuit voltage (OCV).

5. The electrified vehicle of claim 1, wherein the battery impedance model is defined using at least one of a semi-infinite Warburg model, a reflective-boundary Warburg model, a transmissive-boundary Warburg model, or a constant phase element based model.

6. The electrified vehicle of claim 1, wherein the battery impedance model is defined using a Warburg type model.

7. A method of operating an electrified vehicle (EV) having a battery pack including a plurality of battery cells, comprising:
charging and discharging the battery pack according to power limits defined by output of a battery impedance model that associates battery impedance values with frequency-dependent polarization impedance values representing diffusion states of the battery cells, and that receives measured parameters from one or more sensors indicative of the frequency-dependent polarization impedance values of the battery pack.

8. The method of claim 7, wherein the frequency-dependent polarization impedance values are a function of, at least, an open circuit voltage (OCV) detected based on a battery state of charge (SOC) and a defined correlation between multiple battery SOC values and OCV values.

9. The method of claim 7, wherein the measured parameters include a DC voltage and an electric current of the battery pack.

10. The method of claim 9, wherein the frequency-dependent polarization impedance values are a function of the electric current and a polarization voltage estimated using the DC voltage and an open circuit voltage (OCV).

11. The method of claim 9, wherein the battery impedance model is defined using at least one of a semi-infinite Warburg model, a reflective-boundary Warburg model, a transmissive-boundary Warburg model, or a constant phase element based model.

12. The method of claim 7, wherein the frequency-dependent polarization impedance values are a function of on an open circuit voltage (OCV).

13. The method of claim 7, wherein the battery impedance model is defined using a Warburg type model.

14. A system for an electrified vehicle (EV) having a battery pack including a plurality of battery cells, comprising:
a vehicle controller configured to charge and discharge the battery pack according to power limits defined by output of a battery impedance model that associates battery impedance values with frequency-dependent polarization impedance values representing diffusion states of the battery cells, and that receives measured parameters from one or more sensors indicative of the frequency-dependent polarization impedance values of the battery pack.

15. The system of claim 14, wherein the frequency-dependent polarization impedance values are a function of, at least, an open circuit voltage (OCV) detected based on a battery state of charge (SOC) and a defined correlation between multiple battery SOC values and OCV values.

16. The system of claim 14, wherein the measured parameters include a DC voltage and an electric current of the battery pack.

17. The system of claim 16, wherein the frequency-dependent polarization impedance values are a function of the electric current and a polarization voltage estimated using the DC voltage and an open circuit voltage (OCV).

18. The system of claim 14, wherein the battery impedance model is defined using at least one of a semi-infinite Warburg model, a reflective-boundary Warburg model, a transmissive-boundary Warburg model, or a constant phase element based model.

19. The system of claim 14, wherein the frequency-dependent polarization impedance values are a function of on an open circuit voltage (OCV).

20. The system of claim 14, wherein the battery impedance model is defined using a Warburg type model.
